(19) United States
(12) Patent Application Publication
(10) Pub. No.: US 2026/0239800 A1
(43) Pub. Date: Aug. 13, 2026

(54) DISPLAY DEVICE, ELECTRONIC DEVICE INCLUDING THE SAME, AND METHOD OF MANUFACTURING THE DISPLAY DEVICE

(71) Applicant: Samsung Display Co., LTD., Yongin-si (KR)

(72) Inventors: JAEIK KIM, Yongin-si (KR); ARONG KIM, Yongin-si (KR); YOUNGMIN MOON, Yongin-si (KR); HEE JUN YANG, Yongin-si (KR); SAMIN LEE, Yongin-si (KR)

(21) Appl. No.: 19/345,635

(22) Filed: Sep. 30, 2025

(30) Foreign Application Priority Data
Feb. 10, 2025 (KR) 10-2025-0016499

(51) Int. Cl. H10H 29/855; H10H 20/01; H10H 20/853; H10H 29/01; H10H 29/39

(52) U.S. Cl. CPC H10H 29/855; H10H 20/0362; H10H 20/853; H10H 29/012; H10H 29/0363; H10H 29/39

(57) ABSTRACT

A display device includes a base substrate, a circuit element layer, a light-emitting element, a conductive partition wall, a common electrode layer, an encapsulation pattern, and a reflection-reducing layer. The circuit element layer is disposed on the base substrate. The light-emitting element is disposed on the circuit element layer and includes a pixel electrode, a light-emitting pattern, and an opposite electrode. The conductive partition wall is disposed between the circuit element layer and the light-emitting element and is electrically connected with the opposite electrode. The common electrode layer is disposed between the circuit element layer and the conductive partition wall. The encapsulation pattern covers the light-emitting element and surrounds at least a portion of the conductive partition wall. The reflection-reducing layer is disposed on the common electrode layer, surrounds at least a portion of the encapsulation pattern, and has a lower reflectance than a reflectance of the common electrode layer.

This application claims priority to Korean Patent Application No. 10-2025-0016499, filed on Feb. 10, 2025, and all the benefits accruing therefrom under 35 U.S.C. § 119, the content of which in its entirety is herein incorporated by reference.

### BACKGROUND

### 1. Field

The disclosure relates to a display device, an electronic device including the same, and a method of manufacturing the display device. More particularly, the disclosure relates to a display device having improved display quality and an electronic device including the same.

### 2. Description of the Related Art

A display device provides information to a user by displaying various images on a display screen. Generally, the display device displays information within an allocated screen defined as a display area. The display device may output light of various colors to the outside through display elements that include light-emitting materials.

### SUMMARY

When the display device displays images, reflection of external light needs to be minimized. The images may not be clearly visible due to the reflection of external light even though the display device outputs images outwardly. Materials with relatively high reflectance, such as metal electrodes within the display device, may reflect external light, making the display screen appear like a mirror. Therefore, it is desired to reduce the reflection of external light in the display device to enhance its optical quality.

A feature of the disclosure is to provide a display device, an electronic device including the same, and a method of manufacturing the display device, in which light-emitting elements are formed without using a metal mask, and reflection of external light by electrodes or wiring is reduced.

An embodiment of the disclosure provides a display device. The display device in an embodiment of the disclosure includes a base substrate, a circuit element layer, a light-emitting element, a conductive partition wall, a common electrode layer, an encapsulation pattern, and a reflection-reducing layer. The circuit element layer is disposed on the base substrate and includes a pixel circuit. The light-emitting element is disposed on the circuit element layer and includes a pixel electrode electrically connected to the pixel circuit, a light-emitting pattern disposed on the pixel electrode, and an opposite electrode facing the pixel electrode across the light-emitting pattern. The conductive partition wall is disposed between the circuit element layer and the light-emitting element and is electrically connected with the opposite electrode. The common electrode layer is disposed between the circuit element layer and the conductive partition wall and is electrically connected with the conductive partition wall. The encapsulation pattern covers the light-emitting element and surrounds at least a portion of the conductive partition wall. The reflection-reducing layer is disposed on the common electrode layer, surrounds at least a portion of the encapsulation pattern, and has a lower reflectance than a reflectance of the common electrode layer.

In an embodiment, the conductive partition wall may include a first conductive pattern in contact with the common electrode layer, and a second conductive pattern disposed on the first conductive pattern and protruding from a side surface of the first conductive pattern on the first conductive pattern, where a portion of the encapsulation pattern may be disposed between the second conductive pattern and the common electrode layer.

In an embodiment, the light-emitting pattern may surround a portion of a side surface of the conductive partition wall, a portion of the encapsulation pattern may be disposed between the light-emitting pattern and the common electrode layer, and the light-emitting pattern may face the reflection-reducing layer across the encapsulation pattern.

In an embodiment, the opposite electrode may surround the light-emitting pattern, a portion of the encapsulation pattern may be disposed between the opposite electrode and the common electrode layer, and the opposite electrode may face the reflection-reducing layer across the encapsulation pattern.

In an embodiment, the display device may further include a connection electrode disposed between the opposite electrode and the encapsulation pattern, in contact with the opposite electrode and the conductive partition wall, and surrounding a portion of a side surface of the conductive partition wall. The opposite electrode may be electrically connected to the common electrode layer through the conductive partition wall and the connection electrode, and the connection electrode may face the reflection-reducing layer across the encapsulation pattern.

In an embodiment, the display device may further include a pixel defining layer surrounding the pixel electrode to expose a portion of the pixel electrode, and the light-emitting pattern may cover the pixel defining layer and be disposed between the pixel defining layer and the reflection-reducing layer.

In an embodiment, a portion of the reflection-reducing layer may be disposed between the encapsulation pattern and the common electrode layer.

In an embodiment, the reflection-reducing layer may contact the conductive partition wall between the encapsulation pattern and the common electrode layer.

In an embodiment, the encapsulation pattern may include a first portion disposed on the light-emitting element to cover the light-emitting element, a second portion extending from the first portion and surrounding a side surface of the light-emitting element, and a third portion extending from the second portion away from the light-emitting element. A portion of the reflection-reducing layer may be disposed in a recess defined by the second portion and the third portion.

In an embodiment, the display device may further include a lower encapsulation layer disposed on the reflection-reducing layer and the encapsulation pattern, an intermediate encapsulation layer including a planar upper surface and disposed on the lower encapsulation layer, and an upper encapsulation layer disposed on the intermediate encapsulation layer.

In an embodiment, the display device may further include a lower encapsulation layer covering the encapsulation pattern, and an intermediate encapsulation layer covering the lower encapsulation layer and the reflection-reducing layer, where the reflection-reducing layer may be disposed between the lower encapsulation layer and the intermediate encapsulation layer.

In an embodiment, the encapsulation pattern may include a first portion disposed on the light-emitting element to cover the light-emitting element, a second portion extending from the first portion and surrounding a side surface of the light-emitting element, and a third portion extending from the second portion away from the light-emitting element. The lower encapsulation layer may extend along the first, second, and third portions on the encapsulation pattern, and a portion of the reflection-reducing layer may be disposed in a recess defined by the lower encapsulation layer extending along the second and third portions.

In an embodiment, the reflection-reducing layer may include a planar upper surface.

In an embodiment, the encapsulation pattern may include a planar upper surface continuing from the upper surface of the reflection-reducing layer.

In an embodiment, the light-emitting element and the encapsulation pattern may be provided in plural and arranged in a two-dimensional array in a plan view, and a plurality of encapsulation patterns may be separated from each other by the reflection-reducing layer.

In an embodiment of the disclosure, a display device includes a base substrate, a circuit element layer, a light-emitting element, a conductive partition wall, an encapsulation pattern, and a reflection-reducing layer. The circuit element layer is disposed on the base substrate and includes a pixel circuit. The light-emitting element is disposed on the circuit element layer and includes a pixel electrode electrically connected to the pixel circuit, a light-emitting pattern disposed on the pixel electrode, and an opposite electrode facing the pixel electrode across the light-emitting pattern. The conductive partition wall includes a first conductive pattern including a side surface electrically connected with the opposite electrode and a second conductive pattern disposed on the first conductive pattern and protruding from the side surface. The encapsulation pattern includes a first portion disposed on the light-emitting element to cover the light-emitting element, a second portion extending from the first portion and disposed around a side surface of the second conductive pattern, and a third portion extending from the second portion away from the light-emitting element. The reflection-reducing layer surrounds the third portion and has a lower reflectance than a reflectance of the conductive partition wall.

In an embodiment, a portion of the reflection-reducing layer may be disposed in a recess defined by the third portion and the conductive partition wall.

In an embodiment, the light-emitting element may be disposed on the second conductive pattern, and the reflection-reducing layer may be non-overlapping with the first conductive pattern.

In an embodiment, the light-emitting element may be spaced apart from the second conductive pattern, and the reflection-reducing layer may be disposed on the first and second conductive patterns.

An embodiment of the disclosure provides a method of manufacturing a display device. The method of fabricating a display device in an embodiment includes: forming a conductive layer on a circuit element layer; etching the conductive layer to form a first conductive pattern on the circuit element layer and a second conductive pattern protruding from a side surface of the first conductive pattern on the first conductive pattern; forming a light-emitting pattern and an electrode layer on a base substrate including the second conductive pattern to separate light-emitting elements from a dummy layer; forming encapsulation patterns covering the light-emitting elements; forming a reflection-reducing layer to surround at least a portion of a side surface of each of the encapsulation patterns; and forming an encapsulation layer covering the encapsulation patterns and the reflection-reducing layer.

By an embodiment of the disclosure, the stability of the light-emitting element may be ensured through the encapsulation pattern that individually covers the light-emitting element.

Moreover, according to the disclosure, the reflection of external light caused by electrodes and wiring may be reduced by the reflection-reducing layer surrounding the side surface of the encapsulation pattern, thereby improving display quality.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view of an embodiment of a display device according to the disclosure;

FIG. 2 is an example cross-sectional view of the display panel shown in FIG. 1;

FIG. 3 is a plan view illustrating a portion of the display area shown in FIG. 1;

FIG. 4 is an example cross-sectional view illustrating a portion of the display panel taken along line I-I′ of FIG. 3;

FIG. 5 is a diagram for illustrating the role of the reflection-reducing layer shown in FIG. 4;

FIGS. 6 to 9 are example cross-sectional views illustrating a portion of the display panel taken along line I-I′ of FIG. 3;

FIGS. 10A to 10M are example cross-sectional views illustrating an embodiment of a portion of the display panel taken along line II-II′ of FIG. 3 for describing a method of manufacturing a display panel according to the disclosure;

FIG. 11 is an example cross-sectional view illustrating a portion of the display panel taken along line I-I′ of FIG. 3;

FIG. 12 is a block diagram of an embodiment of an electronic device according to the disclosure; and

FIG. 13 illustrates schematic views of another embodiments of electronic devices according to the disclosure.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are described herein, by referring to the drawing figures, to explain features of the disclosure.

In the accompanying drawings, the thicknesses, ratios, and dimensions of the illustrated elements may not be to exact scale and may have been exaggerated for the benefit of effective explanation of the technical features associated with these elements. As such, the disclosure shall not be restricted to the thicknesses, ratios, dimensions, etc. illustrated in the drawings. The term “and/or” encompasses all possible combinations of the associated elements as defined.

An expression such as “comprise” or “include” is intended to specify the presence of a characteristic, a number, a step, an operation, an element, a part, or combinations thereof described in the specification, and shall not be construed to preclude any possibility of presence or addition of one or more other characteristics, numbers, steps, operations, elements, parts, or combinations thereof.

Terms such as “first” and “second” may be used in describing various elements, but the elements shall not be restricted to the terms. The terms may be used to distinguish one element from the other. For instance, the first element may be named the second element, and vice versa, without departing the scope of claims of the disclosure. Unless clearly used otherwise, any expressions in a singular form may include a meaning of a plural form. The term “and/or” shall include the combination of a plurality of listed items or any of the plurality of listed items.

In the following description, first to third directions DR1, DR2, DR3 are defined to describe a display device in an embodiment according to the disclosure. The display device includes an electronic panel (or a display panel), which is formed to include pixels on a plane defined by a first direction DR1 and a second direction DR2. A third direction DR3 is defined as a thickness direction of the display device, and the first to third directions DR1-DR3 may be orthogonal to each other.

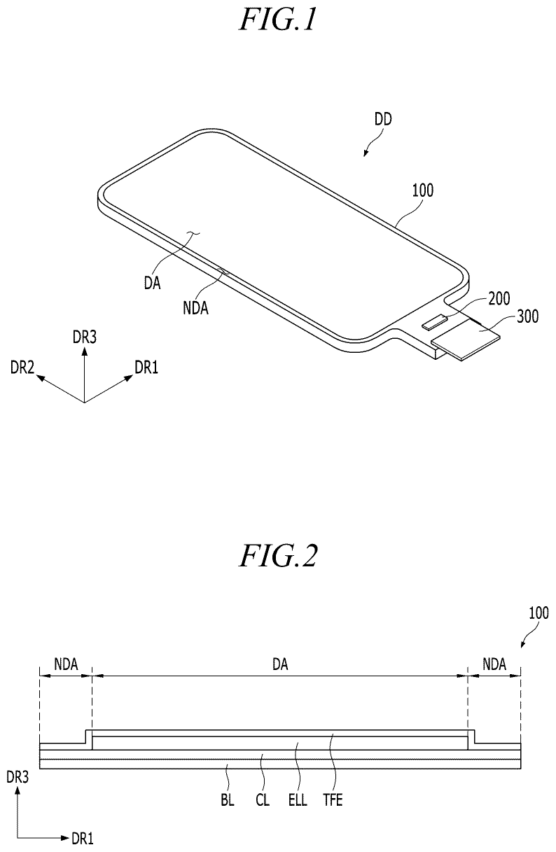

FIG. 1 is a perspective view of an embodiment of a display device according to the disclosure. Referring to FIG. 1, a display device DD includes a display panel 100, a display driver 200, and a circuit board 300. In an embodiment, the display device DD may be applied to various electronic devices such as a tablet personal computer (“PC”), a smartphone, a personal digital assistant (“PDA”), a portable multimedia player (“PMP”), a game console, a television, a personal computer, a notebook computer, or a kiosk, for example. In another embodiment, the display device DD may be applied to a wearable electronic device that provides a visual experience when worn like glasses directly by a user.

The shape of the display device DD is to be understood as illustrative. The display device DD may be modified into various shapes. In an embodiment, the display device DD may have a shape resembling a rectangle with a short side in the first direction DR1 and a long side in the second direction DR2, for example. The corners where the short and long sides meet may be rounded to have a curvature, but are not limited to this shape and may also be formed at right angles. The planar shape of the display device DD is not limited to a rectangle and may be formed similar to other polygons, a circle, or an ellipse.

The display panel 100 may display images. The display panel 100 may include a display area DA and a non-display area NDA. The display area DA may be an area activated according to an electrical signal. The display area DA may include a plurality of pixels, each of which is the minimum unit for emitting light, and may include a light-emitting element (e.g., light-emitting diode) corresponding to each of the plurality of pixels. In an embodiment, the light-emitting element may include, but not limited to, at least one of an organic light-emitting diode (“OLED”) including an organic emission layer, a quantum dot light-emitting diode (“QLED”) including a quantum dot emission layer, an inorganic light-emitting diode including an inorganic semiconductor, or a micro light-emitting diode (“Micro LED”), for example.

Disposed on the display panel 100 may be a plurality of scan lines, a plurality of data lines, and a plurality of power lines that are connected, respectively, to the plurality of pixels. The plurality of scan lines may supply scan signals for selecting pixels for emitting light to the plurality of pixels. The plurality of data lines may supply data voltages received from the display driver 200 to the plurality of pixels. The display panel 100 may output an image based on the data voltages. The plurality of power lines may supply power voltages received from the display driver 200 to the plurality of pixels.

The non-display area NDA may be an area outside the display area DA. The non-display area NDA may surround the display area DA. In an embodiment, the non-display area NDA may include a scan driver configured for supplying scan signals to the scan lines and lines configured for connecting the display driver 200 and the display area DA, for example.

The display driver 200 may output signals and voltages for driving the display panel 100. The display driver 200 may supply data voltages to the data lines. The display driver 200 may supply power voltages to the power lines and scan control signals to the scan driver. The display driver 200 may be implemented as an integrated circuit (“IC”) and disposed (e.g., mounted) on the display panel 100 using a chip-on-glass (“COG”) technique, chip-on-plastic (“COP”) technique, or ultrasonic bonding technique. Unlike the depiction, the display driver 200 may be disposed (e.g., mounted) on the circuit board 300.

The circuit board 300 may be attached to a pad portion of the display panel 100 using an anisotropic conductive film (“ACF”). Lead lines of the circuit board 300 may be electrically connected to the pad portion of the display panel 100. The circuit board 300 may be a flexible printed circuit board, a printed circuit board, or a chip-on-film type flexible film.

The circuit board 300 may include signal lines and electronic components. The electronic components may be connected to the signal lines and electrically connected to the display panel 100 and the display driver 200. The electronic components may generate or process various electrical signals, such as signals for generating images or signals for detecting external input.

FIG. 2 is an example cross-sectional view of the display panel shown in FIG. 1. Referring to FIG. 2, the display panel 100 includes a base substrate BL, a circuit element layer CL, a display element layer ELL, and an encapsulation layer TFE.

The base substrate BL may include or consist of various materials such as glass, metal, or plastic. The base substrate BL may include a transparent flexible substrate. The base substrate BL may include a substrate having a substantially constant refractive index in the wavelength range of the visible light spectrum.

The circuit element layer CL is disposed on the base substrate BL. The circuit element layer CL may include at least one insulating layer and a circuit element. The circuit element includes a plurality of transistors. The circuit element layer CL further includes a plurality of signal lines, such as the scan lines, data lines, and power lines described above, and a pixel circuit implemented with the circuit elements. The pixel circuit is electrically connected to the plurality of signal lines and may drive the display area DA to output light of luminance corresponding to a data voltage based on the received scan signal. The insulating layer of the circuit element layer CL may include at least one inorganic film and/or at least one organic film.

The display element layer ELL is disposed on the circuit element layer CL. The display element layer ELL may include a plurality of light-emitting elements (e.g., light-emitting diodes). One light-emitting diode corresponds to one pixel PX. The display element layer ELL may include organic light-emitting diodes as the light-emitting diodes. The display element layer ELL may include a pixel defining layer, e.g., an organic material. The display element layer ELL may overlap the display area DA and may be non-overlapping with the non-display area NDA.

The encapsulation layer TFE is disposed on the circuit element layer CL and the display element layer ELL. The encapsulation layer TFE covers the display element layer ELL. The encapsulation layer TFE may include a plurality of thin films. The encapsulation layer TFE may include at least one stacked inorganic film and/or at least one stacked organic film. The encapsulation layer TFE protects the display element layer ELL from moisture, oxygen, and dust. The encapsulation layer TFE may be disposed on the display element layer ELL in the display area DA and may be disposed on the circuit element layer CL in the non-display area NDA.

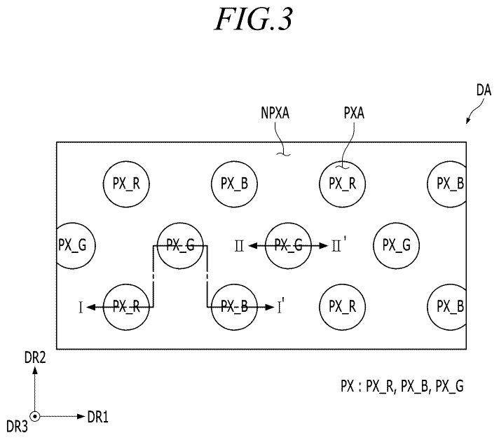

FIG. 3 is a plan view illustrating a portion of the display area of FIG. 1. Referring to FIG. 3, the display area DA includes a light-emitting area PXA and a non-light-emitting area NPXA. The light-emitting area PXA may be an area that emits light provided from a light-emitting diode. The non-light-emitting area NPXA may surround the light-emitting area PXA around the periphery of the light-emitting area PXA. The light-emitting area PXA may be defined by a pixel defining layer, which will be described later.

The display area DA may include a plurality of pixels PX_R, PX_G, and PX_B arranged in the light-emitting area PXA. The plurality of pixels PX_R, PX_G, and PX_B may include a first pixel PX_R, a second pixel PX_G, and a third pixel PX_B, which emit light of different colors. The first to third pixels PX_R, PX_G, and PX_B may emit red, green, and blue light, respectively, and the emission color in each of the first to third pixels PX_R, PX_G, and PX_B may vary depending on the type of light-emitting diode used, which will be described later.

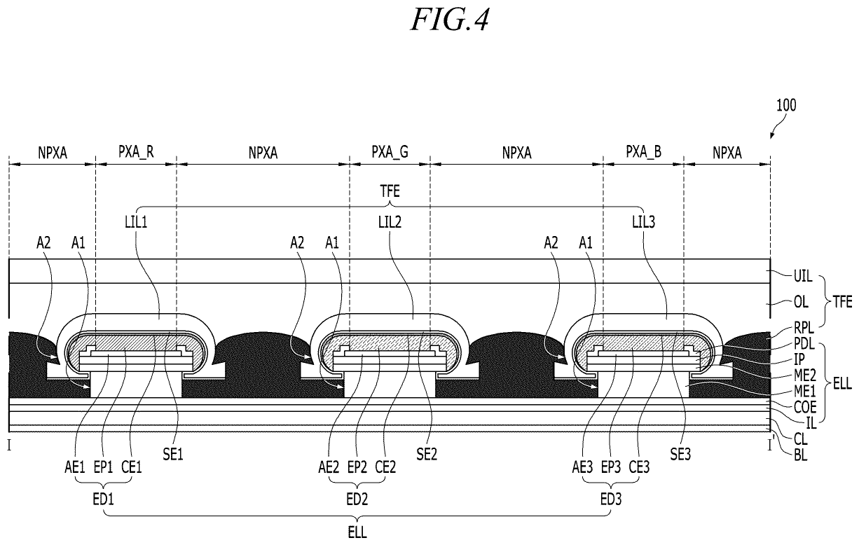

The plurality of pixels PX_R, PX_G, and PX_B may be arranged in a Pentile type layout, e.g., a diamond Pentile type. In an embodiment, the first pixel PX_R and the third pixel PX_B may be spaced apart from each other in the first direction DR1 and arranged alternately along the first direction DR1 and the second direction DR2. The second pixel PX_G may be spaced apart from second pixels PX_G next (adjacent) to each other in the first direction DR1 and the second direction DR2, for example. The second pixel PX_G and either the first pixel PX_R or the third pixel PX_B may be arranged alternately in a direction within the plane defined by the first direction DR1 and the second direction DR2.
FIG. 4 is an example cross-sectional view illustrating a portion of the display panel taken along line I-I′ of FIG. 3. It is to be understood that FIG. 4 shows an enlarged view of the first to third pixels PX_R, PX_G, and PX_B shown in FIG. 3. A first light-emitting area PXA_R, a second light-emitting area PXA_G, and a third light-emitting area PXA_B correspond to the light-emitting area PXA of FIG. 3 and are to be understood as areas where each of the first to third pixels PX_R, PX_G, and PX_B emits light. A non-light-emitting area NPXA described with reference to FIG. 3 is provided between the plurality of pixels PX_R, PX_G, and PX_B.

Referring to FIG. 4, the display panel 100 includes a base substrate BL, a circuit element layer CL, a display element layer ELL, and an encapsulation layer TFE. The base substrate BL, the circuit element layer CL, the display element layer ELL, and the encapsulation layer TFE correspond, respectively, to the base substrate BL, the circuit element layer CL, the display element layer ELL, and the encapsulation layer TFE of FIG. 2. As described above, the base substrate BL may include or consist of various materials such as glass, metal, or plastic. The circuit element layer CL is disposed on the base substrate BL and includes a pixel circuit configured to control activation and light emission of the first to third pixels PX_R, PX_G, and PX_B.

The display element layer ELL may be disposed on the circuit element layer CL. The display element layer ELL may include an insulating layer IL, a common electrode layer COE, a first conductive pattern ME1, a second conductive pattern ME2, an insulating pattern IP, light-emitting diodes ED1, ED2, and ED3, a pixel defining layer PDL, and connection electrodes SE1, SE2, and SE3. The light-emitting diodes ED1, ED2, and ED3 may include pixel electrodes AE1, AE2, and AE3, light-emitting patterns EP1, EP2, and EP3, and opposite electrodes CE1, CE2, and CE3.

The insulating layer IL may be disposed on the circuit element layer CL. The insulating layer IL may provide a contact hole for electrically connecting the light-emitting diodes ED1, ED2, and ED3 to the pixel circuit in the circuit element layer CL described above. Through the contact hole, the pixel circuit of the circuit element layer CL is electrically connected to the pixel electrodes AE1, AE2, and AE3 of the light-emitting diodes ED1, ED2, and ED3. This electrical connection may be provided at a position different from the cross-section shown in FIG. 4.

The common electrode layer COE may be disposed on the insulating layer IL. The common electrode layer COE may be commonly disposed over the entirety of the display area DA described above and may provide a common voltage to the opposite electrodes CE1, CE2, and CE3. The common electrode layer COE may be disposed to overlap the first to third light-emitting areas PXA_R, PXA_G, and PXA_B. The common electrode layer COE may provide a contact hole for electrically connecting the pixel circuit to the pixel electrodes AE1, AE2, and AE3. This contact hole may be in communication with the contact hole of the insulating layer IL. The insulating pattern IP, configured to block electrical connection between the pixel electrodes AE1, AE2, and AE3 and the common electrode layer COE, may cover a side surface of the contact hole.

The first conductive pattern ME1 may be disposed on the common electrode layer COE. The first conductive pattern ME1 may be electrically connected with the common electrode layer COE. The first conductive pattern ME1 may be disposed to overlap the first to third light-emitting areas PXA_R, PXA_G, and PXA_B. The first conductive pattern ME1 may include a plurality of conductive patterns, each corresponding to one of a plurality of pixels and physically spaced apart from one another. The first conductive pattern ME1 may provide a contact hole for electrically connecting the pixel circuit to the pixel electrodes AE1, AE2, and AE3. This contact hole may be in communication with the contact hole of the common electrode layer COE. The insulating pattern IP, configured to block electrical connection between the pixel electrodes AE1, AE2, and AE3 and the first conductive pattern ME1, may cover a side surface of the contact hole.

The second conductive pattern ME2 may be disposed on the first conductive pattern ME1. The second conductive pattern ME2 may be electrically connected with the first conductive pattern ME1. The second conductive pattern ME2 may be disposed to overlap the first to third light-emitting areas PXA_R, PXA_G, and PXA_B. The second conductive pattern ME2 may provide a contact hole for electrically connecting the pixel circuit with the pixel electrodes AE1, AE2, and AE3. This contact hole may be in communication with the contact hole of the first conductive pattern ME1. The insulating pattern IP, configured to block electrical connection between the pixel electrodes AE1, AE2, and AE3 and the second conductive pattern ME2, may cover a side surface of the contact hole.

A side surface of the second conductive pattern ME2 may protrude beyond a side surface of the first conductive pattern ME1. With the protruding shape of the second conductive pattern ME2, the light-emitting diodes ED1, ED2, and ED3 may be patterned on a pixel-by-pixel basis without using a mask defining openings at a pixel scale (e.g., a fine metal mask (“FMM”)). That is, high-resolution pixel formation may be achieved. Details related to this patterning will be described later. The thickness of the first conductive pattern ME1 may be greater than that of the second conductive pattern ME2, although this is not limiting.

The first and second conductive patterns ME1 and ME2 may include a conductive material. In an embodiment, the conductive material may include a metal, a transparent conductive oxide (“TCO”), or any combinations thereof, for example. The metal may include gold (Au), silver (Ag), aluminum (Al), magnesium (Mg), lithium (Li), molybdenum (Mo), titanium (Ti), copper (Cu), or alloys thereof. The transparent conductive oxide may include indium tin oxide (“ITO”), indium zinc oxide (“IZO”), zinc oxide, indium oxide, indium gallium oxide, indium gallium zinc oxide (“IGZO”), or aluminum zinc oxide. In an embodiment, the first conductive pattern ME1 may include a different material than that of the second conductive pattern ME2, and the second conductive pattern ME2 may include the same material as that of the common electrode layer COE, for example, although this is not limiting.

The insulating pattern IP may be disposed on the second conductive pattern ME2. A side surface of the insulating pattern IP may be aligned with a side surface of the second conductive pattern ME2. The insulating pattern IP may block electrical connection between the first and second conductive patterns ME1 and ME2 and the pixel electrodes AE1, AE2, and AE3. The insulating pattern IP may be disposed to overlap the first to third light-emitting areas PXA_R, PXA_G, and PXA_B. Although not shown in FIG. 4, the insulating pattern IP may cover a side surface of a contact hole for electrically connecting the pixel circuit of the circuit element layer CL and the pixel electrodes AE1, AE2, and AE3. The pixel electrodes AE1, AE2, and AE3 may be isolated from the common electrode layer COE and the first and second conductive patterns ME1 and ME2 through the insulating pattern IP.

The light-emitting diodes ED1, ED2, and ED3 may be disposed on the first and second conductive patterns ME1 and ME2 and the insulating pattern IP. As the light-emitting diodes ED1, ED2, and ED3 are uniformly formed on conductive partition walls such as the first and second conductive patterns ME1 and ME2, shadow regions may be prevented during the deposition process. The conductive partition wall may facilitate physical separation between the light-emitting diodes ED1, ED2, and ED3 during patterning, without a mask (e.g., a fine metal mask). Accordingly, the display panel 100 may be provided with relatively high resolution readily implemented.

The pixel electrodes AE1, AE2, and AE3 may be disposed on the insulating pattern IP. The pixel electrodes AE1, AE2, and AE3 may be disposed to overlap the first to third light-emitting areas PXA_R, PXA_G, and PXA_B. The pixel electrodes AE1, AE2, and AE3 serve as anode electrodes of the light-emitting diodes ED1, ED2, and ED3 and are electrically connected with the pixel circuit of the circuit element layer CL through the contact holes described above. The pixel electrodes AE1, AE2, and AE3 may be connected to the circuit element layer CL through the contact holes. The pixel electrodes AE1, AE2, and AE3 may be transmissive electrodes, semi-transmissive electrodes, or reflective electrodes. The pixel electrodes AE1, AE2, and AE3 may include a single-layer or a multilayer structure. In an embodiment, the pixel electrodes AE1, AE2, and AE3 may include multiple layers including indium tin oxide (“ITO”) and silver (Ag), for example.

The light-emitting patterns EP1, EP2, and EP3 may be disposed on the pixel electrodes AE1, AE2, and AE3. The light-emitting patterns EP1, EP2, and EP3 may be disposed to overlap the first to third light-emitting areas PXA_R, PXA_G, and PXA_B. The light-emitting patterns EP1, EP2, and EP3 include light-emitting materials. The light-emitting patterns EP1, EP2, and EP3 may include organic materials that include fluorescent or phosphorescent materials emitting red, green, or blue light, respectively. The light-emitting patterns EP1, EP2, and EP3 may include small-molecule organic materials or polymer organic materials.

The light-emitting patterns EP1, EP2, and EP3 may be formed to surround the side surfaces of the second conductive pattern ME2 and the insulating pattern IP. In an embodiment, the light-emitting patterns EP1, EP2, and EP3 may be patterned in regions defined by the second conductive pattern ME2, thereby surrounding the side surfaces of the second conductive pattern ME2 and the insulating pattern IP, for example. The light-emitting patterns EP1, EP2, and EP3 may be readily patterned on a pixel-by-pixel basis by the partition wall structure of the first and second conductive patterns ME1 and ME2. In the process of forming the light-emitting patterns EP1, EP2, and EP3, a light-emitting layer may also be formed on the common electrode layer COE, and during the removal process of the light-emitting layer, a first recess A1 may be formed. Details regarding this will be described later.

The opposite electrodes CE1, CE2, and CE3 may be disposed on the light-emitting patterns EP1, EP2, and EP3. The opposite electrodes CE1, CE2, and CE3 may be disposed to overlap the first to third light-emitting areas PXA_R, PXA_G, and PXA_B. The opposite electrodes CE1, CE2, and CE3 serve as cathode electrodes of the light-emitting diodes ED1, ED2, and ED3 and are electrically connected to the common electrode layer COE. The opposite electrodes CE1, CE2, and CE3 may be connected to the common electrode layer COE through the connection electrodes SE1, SE2, and SE3. The opposite electrodes CE1, CE2, and CE3 may include or consist of various materials having conductivity, such as metal, transparent conductive oxide (“TCO”), or conductive polymer material. In an embodiment, the opposite electrodes CE1, CE2, and CE3 may include silver (Ag), magnesium (Mg), lead (Pb), copper (Cu), or compounds thereof, for example.

The opposite electrodes CE1, CE2, and CE3 may be formed to cover upper surfaces and at least a portion of the side surfaces of the light-emitting patterns EP1, EP2, and EP3. In an embodiment, the opposite electrodes CE1, CE2, and CE3 may be patterned in regions defined by the second conductive pattern ME2 to cover the upper and side surfaces of the light-emitting patterns EP1, EP2, and EP3, for example. During the process of forming the opposite electrodes CE1, CE2, and CE3, a conductive layer may be formed on the previously described light-emitting layer, and a first recess A1 may be formed during the removal of the light-emitting and conductive layers.

Although not depicted, the light-emitting diodes ED1, ED2, and ED3 may further include a hole control layer, such as a hole transport layer (“HTL”) and a hole injection layer (“HIL”), between the light-emitting patterns EP1, EP2, and EP3 and the pixel electrodes AE1, AE2, and AE3. Although not depicted, the light-emitting diodes ED1, ED2, and ED3 may further include an electron control layer, such as an electron transport layer (“ETL”) and an electron injection layer (“EIL”), between the light-emitting patterns EP1, EP2, and EP3 and the opposite electrodes CE1, CE2, and CE3.

The pixel defining layer PDL may be disposed on the insulating pattern IP. The pixel defining layer PDL may surround the pixel electrodes AE1, AE2, and AE3 to expose at least a portion of the pixel electrodes AE1, AE2, and AE3. In an embodiment, the pixel defining layer PDL may surround a portion of the upper and side surfaces of the pixel electrodes AE1, AE2, and AE3, for example. The pixel defining layer PDL defines the first to third light-emitting areas PXA_R, PXA_G, and PXA_B. The pixel defining layer PDL may include a dye or pigment of black color. In an embodiment, the pixel defining layer PDL may include an inorganic insulating material, such as silicon nitride (SiNx), for example.

The pixel defining layer PDL may include a plurality of light-blocking patterns, each corresponding to one of the plurality of pixels and physically spaced apart from each other. A side surface of the pixel defining layer PDL may be aligned with a side surface of the insulating pattern IP and a side surface of the second conductive pattern ME2. Each of the plurality of light-blocking patterns may be covered by the light-emitting patterns EP1, EP2, and EP3. The light-blocking patterns may be separated from each other in the process of forming the light-emitting diodes ED1, ED2, and ED3 on the conductive partition walls in order to form high-resolution pixels. As a result, the pixel defining layer PDL may not cover the non-light-emitting area NPXA. A reflection-reducing layer RPL, which will be described later, may cover electrodes and wirings exposed in the non-light-emitting area NPXA, such as the common electrode layer COE.

The connection electrodes SE1, SE2, and SE3 may be disposed on the opposite electrodes CE1, CE2, and CE3. The connection electrodes SE1, SE2, and SE3 may be disposed to overlap the first to third light-emitting areas PXA_R, PXA_G, and PXA_B. The connection electrodes SE1, SE2, and SE3 may each correspond to one pixel and may be spaced apart from each other to be physically separated. The connection electrodes SE1, SE2, and SE3 may cover the opposite electrodes CE1, CE2, and CE3, the lower surfaces of the second conductive pattern ME2, and surround a portion of the side surfaces of the first conductive pattern ME1. The connection electrodes SE1, SE2, and SE3 may further extend in a direction away from the side surfaces of the first conductive pattern ME1. Owing to this structure, the first recess A1 may be defined between the connection electrodes SE1, SE2, and SE3 and the common electrode layer COE. Further, a second recess A2 may be formed due to the extending structure of the connection electrodes SE1, SE2, and SE3.

The connection electrodes SE1, SE2, and SE3 may include a conductive material. In an embodiment, the connection electrodes SE1, SE2, and SE3 may include a metal, a transparent conductive oxide (“TCO”), or a combination thereof, for example. The metal may include gold (Au), silver (Ag), aluminum (Al), magnesium (Mg), lithium (Li), molybdenum (Mo), titanium (Ti), copper (Cu), or alloys thereof. The transparent conductive oxide may include indium tin oxide (“ITO”), indium zinc oxide (“IZO”), zinc oxide, indium oxide, indium gallium oxide, indium gallium zinc oxide (“IGZO”), or aluminum zinc oxide.

The connection electrodes SE1, SE2, and SE3 may electrically connect the opposite electrodes CE1, CE2, and CE3 with the first and second conductive patterns ME1 and ME2. The opposite electrodes CE1, CE2, and CE3 may receive a common voltage through the connection electrodes SE1, SE2, and SE3 and the first and second conductive patterns ME1 and ME2. To this end, the connection electrodes SE1, SE2, and SE3 may contact the opposite electrodes CE1, CE2, and CE3 and the first and second conductive patterns ME1 and ME2. The connection electrodes SE1, SE2, and SE3 may contact the lower surfaces of the second conductive pattern ME2. The connection electrodes SE1, SE2, and SE3 may extend along and contact the side surfaces of the first conductive pattern ME1.

The encapsulation layer TFE may be disposed on the display element layer ELL. The encapsulation layer TFE may protect the display element layer ELL from moisture, oxygen, dust particles, and foreign substances. The encapsulation layer TFE may include encapsulation patterns LIL1, LIL2, and LIL3, a reflection-reducing layer RPL, an intermediate encapsulation layer OL, and an upper encapsulation layer UIL. The components disposed in the encapsulation layer TFE are to be understood as exemplary, and additional encapsulation layers or encapsulation patterns may be provided.

The encapsulation patterns LIL1, LIL2, and LIL3 may be disposed on the connection electrodes SE1, SE2, and SE3 to cover the upper surfaces of the connection electrodes SE1, SE2, and SE3. The encapsulation patterns LIL1, LIL2, and LIL3 may be disposed to overlap the first to third light-emitting areas PXA_R, PXA_G, and PXA_B. The encapsulation patterns LIL1, LIL2, and LIL3 may each correspond to a single pixel and may be spaced apart from each other to be physically separated. The encapsulation patterns LIL1, LIL2, and LIL3 extend along the anchor shapes of the connection electrodes SE1, SE2, and SE3 and thus may robustly cover and surround upper, lateral, and lower portions of the light-emitting diodes ED1, ED2, and ED3.

The encapsulation patterns LIL1, LIL2, and LIL3 may be spaced apart from the common electrode layer COE. The first recess A1 may be defined between the encapsulation patterns LIL1, LIL2, and LIL3 and the common electrode layer COE. Based on the shape in which the encapsulation patterns LIL1, LIL2, and LIL3 cover the connection electrodes SE1, SE2, and SE3, the second recess A2 may be formed on the encapsulation patterns LIL1, LIL2, and LIL3. The encapsulation patterns LIL1, LIL2, and LIL3 may include an inorganic material but are not limited thereto and may also include an organic material.

The reflection-reducing layer RPL may be disposed on the circuit element layer CL and may surround the first conductive pattern ME1 and portions of the encapsulation patterns LIL1, LIL2, and LIL3. The reflection-reducing layer RPL may surround the side surfaces of the first conductive pattern ME1 and at least a portion of the side surfaces and upper surfaces of the encapsulation patterns LIL1, LIL2, and LIL3. The reflection-reducing layer RPL may surround the side surfaces of the display element layer ELL protruding from the circuit element layer CL in the third direction DR3. As a result, the reflection-reducing layer RPL is disposed to face the light-emitting diodes ED1, ED2, and ED3, the connection electrodes SE1, SE2, and SE3, and the pixel defining layer PDL across the encapsulation patterns LIL1, LIL2, and LIL3. The reflection-reducing layer RPL overlaps the non-light-emitting area NPXA.

The reflection-reducing layer RPL may be provided to reduce the reflection of external light caused by various electrodes and wirings in the display panel 100. In an embodiment, the reflection-reducing layer RPL may include a material having a lower reflectance than electrodes and wirings such as the common electrode layer COE, the first and second conductive patterns ME1 and ME2, and the connection electrodes SE1, SE2, and SE3, for example. The reflection-reducing layer RPL may include a dye or pigment of black color. In an embodiment, the reflection-reducing layer RPL may include the same material as that of the pixel defining layers PDL, for example. In an embodiment, the reflection-reducing layer RPL may include an inorganic insulating material such as silicon nitride (SiNx), for example.

The reflection-reducing layer RPL may be disposed on the common electrode layer COE to reduce the reflection of external light by the common electrode layer COE. The reflection-reducing layer RPL may be disposed around the side surfaces of the first conductive pattern ME1 to reduce the reflection of external light caused by the first conductive pattern ME1. To this end, the reflection-reducing layer RPL may fill at least a portion of the first recess A1. In an embodiment, the reflection-reducing layer RPL may contact the first conductive pattern ME1, for example. The reflection-reducing layer RPL may be disposed to cover portions of the connection electrodes SE1, SE2, and SE3 and the encapsulation patterns LIL1, LIL2, and LIL3 that extend in a direction away from the first conductive pattern ME1. The reflection-reducing layer RPL may fill at least a portion of the second recess A2. Accordingly, in the non-light-emitting area NPXA, the reflection-reducing layer RPL may reduce the reflection of external light caused by the connection electrodes SE1, SE2, and SE3.

The intermediate encapsulation layer OL may be disposed on the encapsulation patterns LIL1, LIL2, and LIL3 and the reflection-reducing layer RPL to cover the encapsulation patterns LIL1, LIL2, and LIL3 and the reflection-reducing layer RPL. The intermediate encapsulation layer OL may provide a planar upper surface. The intermediate encapsulation layer OL may include an organic material but is not limited thereto and may be configured with a plurality of layers including an inorganic material or both organic and inorganic materials.

The upper encapsulation layer UIL may be disposed on the intermediate encapsulation layer OL. The upper encapsulation layer UIL may include an inorganic material but is not limited thereto and may be configured with a plurality of layers including an organic material or both organic and inorganic materials.

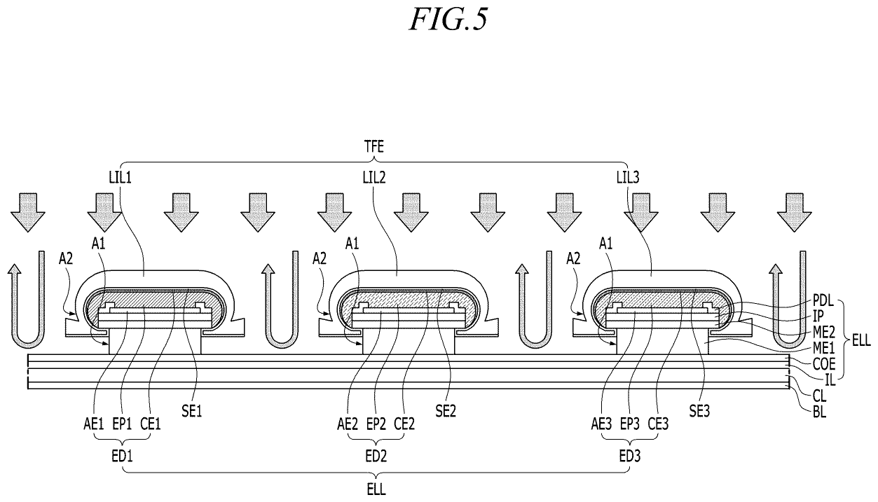

FIG. 5 is a diagram for illustrating the role of the reflection-reducing layer shown in FIG. 4. Referring to FIG. 5, the display element layer ELL of FIG. 4 is shown. As described above, the light-emitting diodes ED1, ED2, and ED3 of the display element layer ELL are disposed on conductive partition walls such as the first and second conductive patterns ME1 and ME2. The pixel defining layer PDL of the display element layer ELL is disposed inside the light-emitting diodes ED1, ED2, and ED3. Accordingly, electrodes and wirings such as the common electrode layer COE may be exposed in the non-light-emitting area NPXA. These electrodes and wirings may reflect external light, making the display screen appear like a mirror.

The reflection-reducing layer RPL shown in FIG. 4 may reduce the reflection effect caused by external light, by covering the exposed electrodes and wirings. The reflection-reducing layer RPL may be disposed to overlap the non-light-emitting area NPXA and cover the electrodes and wirings. In particular, the reflection-reducing layer RPL may be disposed in the first recess A1 and the second recess A2 formed during the fabrication process of the display element layer ELL, thereby minimizing reflective regions caused by electrodes and wirings.

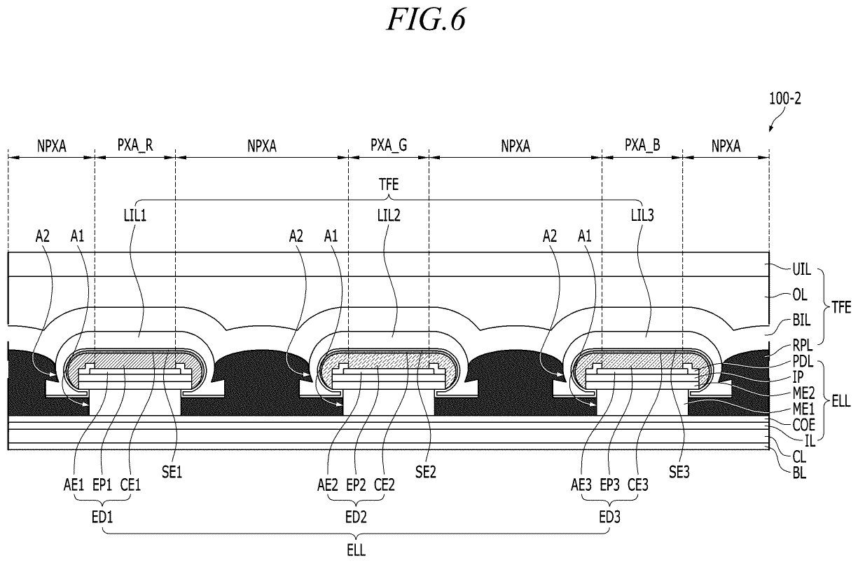

FIGS. 6 to 9 are example cross-sectional views illustrating a portion of the display panel taken along line I-I′ of FIG. 3. Display panels 100-2, 100-3, 100-4, 100-5 shown in FIGS. 6 to 9 are to be understood to represent different embodiments from the display panel 100 shown in FIG. 4. The base substrate BL, the circuit element layer CL, and the display element layer ELL in FIGS. 6 to 9 are substantially the same as those in FIG. 4 and thus will not be described redundantly. Hereinafter, the encapsulation layer TFE will be mainly described for being different from FIG. 4.

Referring to FIG. 6, the encapsulation layer TFE of the display panel 100-2 includes encapsulation patterns LIL1, LIL2, and LIL3, a reflection-reducing layer RPL, a lower encapsulation layer BIL, an intermediate encapsulation layer OL, and an upper encapsulation layer UIL. Compared to FIG. 4, the lower encapsulation layer BIL may be additionally disposed between the reflection-reducing layer RPL and the intermediate encapsulation layer OL. The lower encapsulation layer BIL may be disposed on the encapsulation patterns LIL1, LIL2, and LIL3 and the reflection-reducing layer RPL to cover the encapsulation patterns LIL1, LIL2, and LIL3 and the reflection-reducing layer RPL. The lower encapsulation layer BIL may include, but not limited to, an inorganic material.

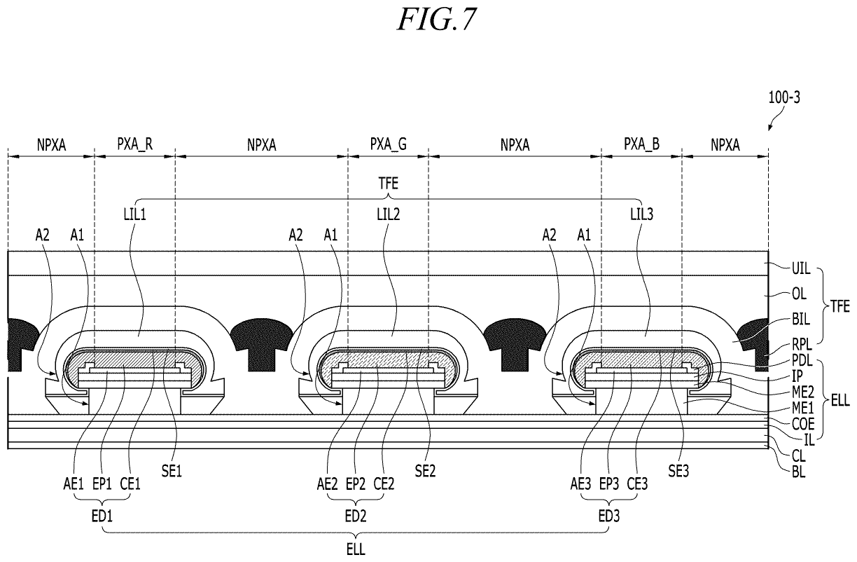

Referring to FIG. 7, the encapsulation layer TFE of the display panel 100-3 includes encapsulation patterns LIL1, LIL2, and LIL3, a reflection-reducing layer RPL, a lower encapsulation layer BIL, an intermediate encapsulation layer OL, and an upper encapsulation layer UIL. Compared to FIG. 6, the lower encapsulation layer BIL is disposed between the encapsulation patterns LIL1, LIL2, and LIL3 and the reflection-reducing layer RPL. Accordingly, the reflection-reducing layer RPL may fill the second recess A2 without filling the first recess A1. The closer the reflection-reducing layer RPL is to the upper encapsulation layer UIL, the more broadly the reflection-reducing layer RPL may cover the non-light-emitting area NPXA. In an embodiment, the reflection-reducing layer RPL may have a height sufficient to overlap the non-light-emitting area NPXA in which the first recess A1 is formed, for example.

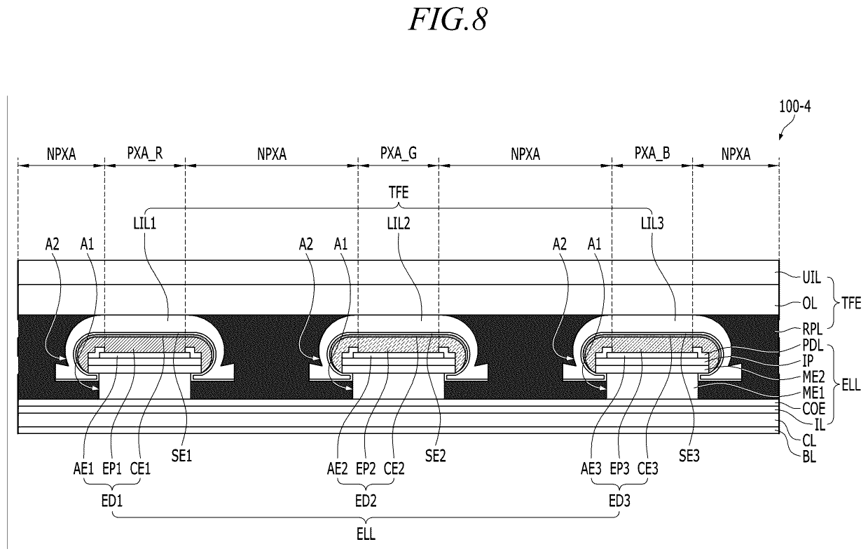

Referring to FIG. 8, the encapsulation layer TFE of the display panel 100-4 includes encapsulation patterns LIL1, LIL2, and LIL3, a reflection-reducing layer RPL, an intermediate encapsulation layer OL, and an upper encapsulation layer UIL. Compared to FIG. 4, the reflection-reducing layer RPL may provide a planar upper surface together with the encapsulation patterns LIL1, LIL2, and LIL3. In an embodiment, owing to the provision of a planar upper surface, the intermediate encapsulation layer OL may be omitted, for example. After forming the reflection-reducing layer RPL, a planar upper surface may be formed through polishing or ashing.

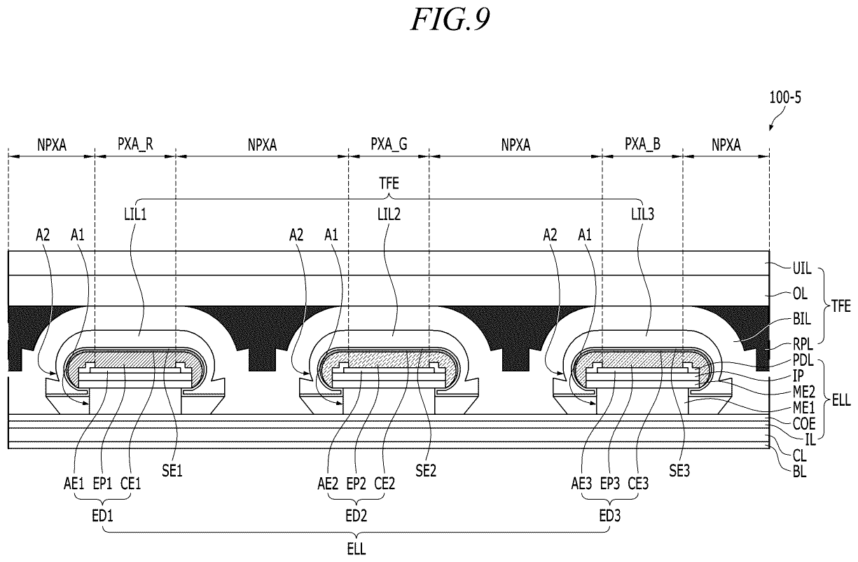

Referring to FIG. 9, the encapsulation layer TFE of the display panel 100-5 includes encapsulation patterns LIL1, LIL2, and LIL3, a reflection-reducing layer RPL, a lower encapsulation layer BIL, an intermediate encapsulation layer OL, and an upper encapsulation layer UIL. As in FIG. 7, the lower encapsulation layer BIL is disposed between the encapsulation patterns LIL1, LIL2, and LIL3 and the reflection-reducing layer RPL. Moreover, as in FIG. 8, the reflection-reducing layer RPL may provide a planar upper surface together with the lower encapsulation layer BIL (or the encapsulation patterns LIL1, LIL2, and LIL3). In an embodiment, owing to the provision of a planar upper surface, the intermediate encapsulation layer OL may be omitted, for example. After forming the reflection-reducing layer RPL, a planar upper surface may be formed through polishing or ashing.

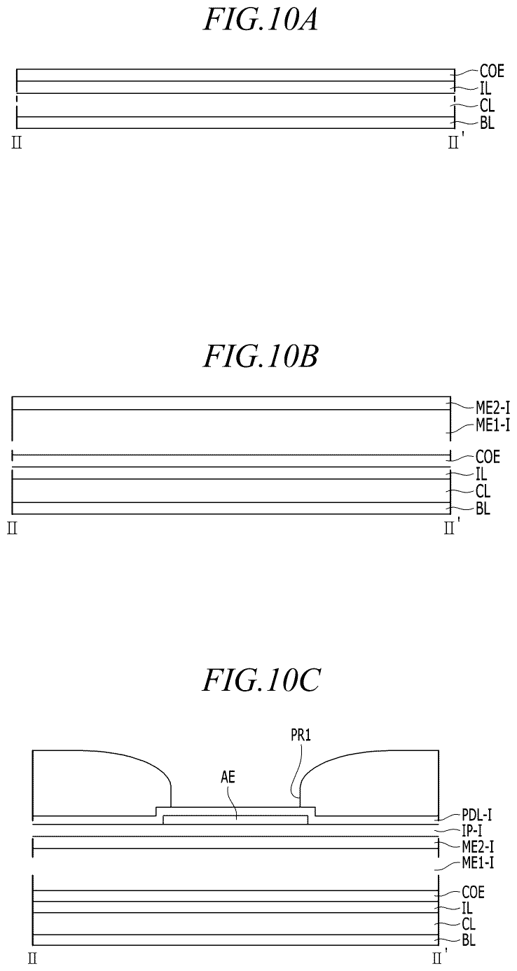

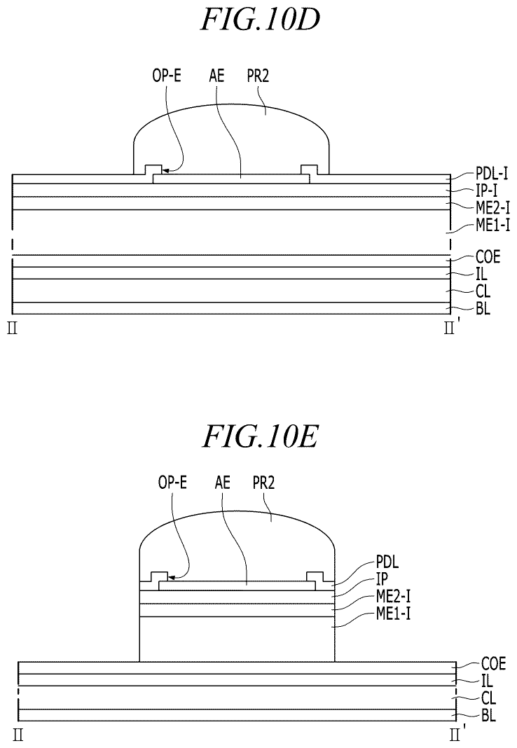

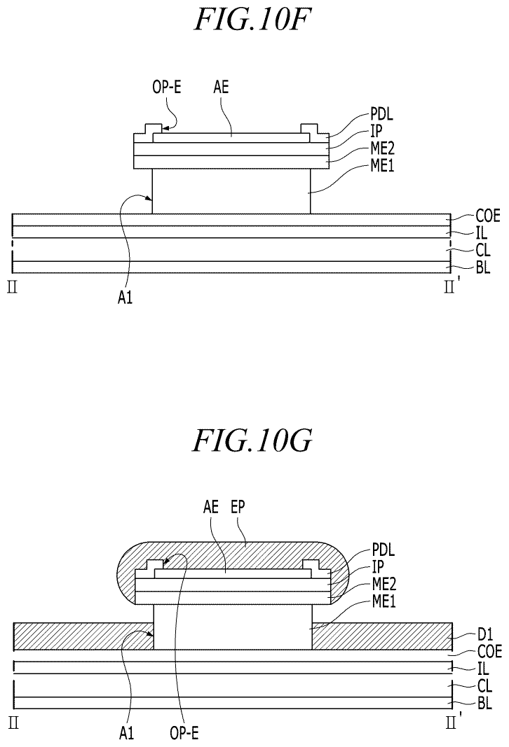

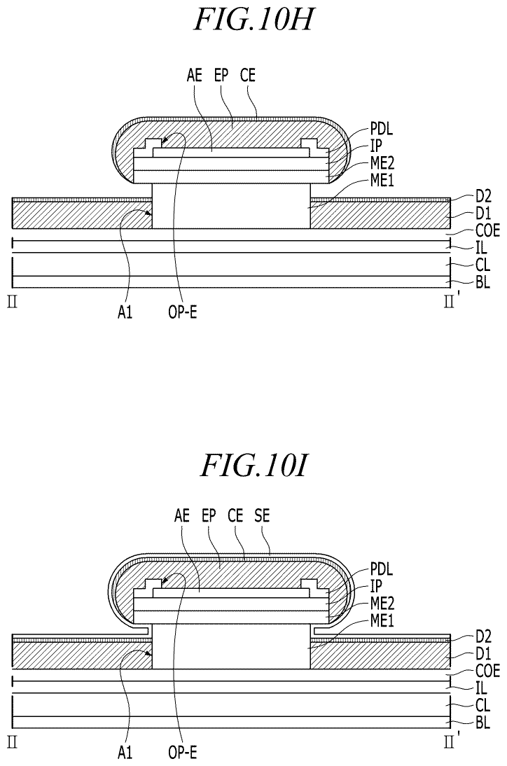

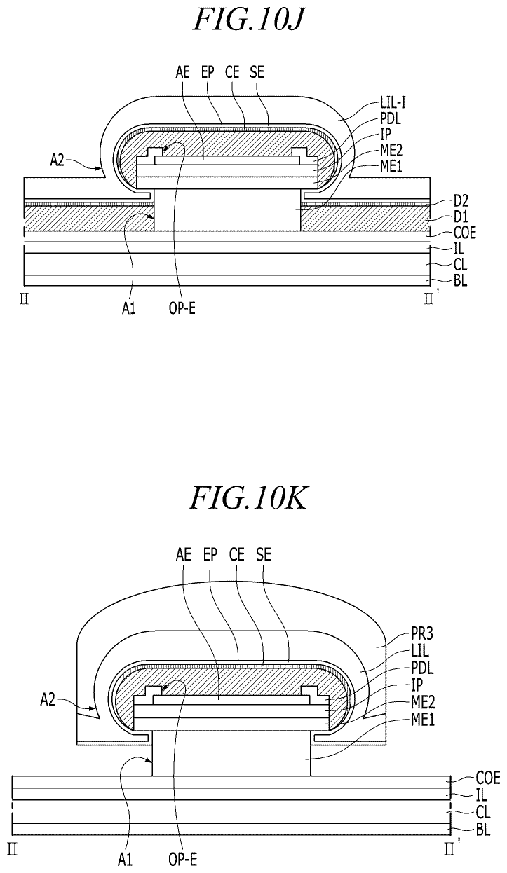

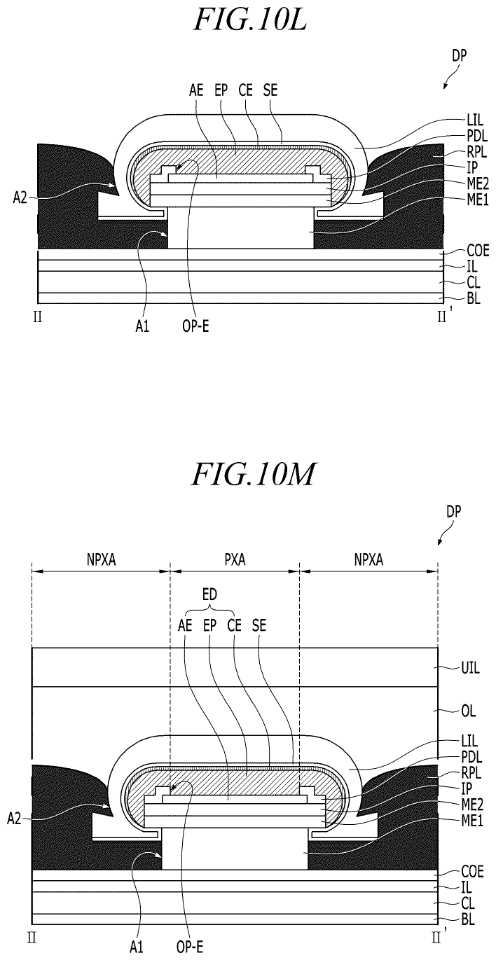

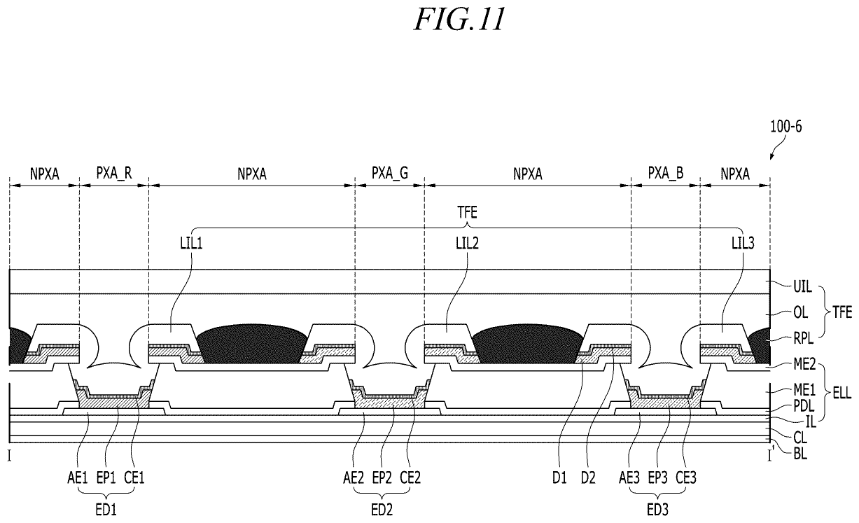

FIGS. 10A to 10M are example cross-sectional views illustrating an embodiment of a portion of the display panel taken along line II-II′ of FIG. 3 for describing a method of manufacturing a display panel according to the disclosure. FIGS. 10A to 10M illustrate a process of forming a pixel including one light-emitting diode (e.g., the second light-emitting diode ED2 of FIG. 3).

Referring to FIG. 10A, in the method of manufacturing the display panel 100 in an embodiment according to the disclosure, a circuit element layer CL including a pixel circuit is formed on a base substrate BL. The circuit element layer CL may be formed by patterning an insulating layer, a semiconductor layer, and a conductive layer—each formed by processes such as coating and/or deposition—through photolithography and etching. Thereafter, an insulating layer IL is formed on the circuit element layer CL, and a common electrode layer COE is formed on the insulating layer IL. The common electrode layer COE may be commonly disposed over the entirety of the display area DA and may be formed to provide a common voltage.

Referring to FIG. 10B, a first conductive layer ME1-I and a second conductive layer ME2-I may be formed on the common electrode layer COE for forming a conductive partition wall. The first conductive layer ME1-I is formed on the common electrode layer COE and shall be understood as a structure before patterning the first conductive pattern ME1 described with reference to FIG. 4. The second conductive layer ME2-I is formed on the first conductive layer ME1-I and shall be understood as a structure before patterning the second conductive pattern ME2 described with reference to FIG. 4.

The first and second conductive layers ME1-I, and ME2-I may be formed by a deposition process of a conductive material. In an embodiment, the conductive material may include a metal, a transparent conductive oxide (“TCO”), or any combinations thereof, for example. The metal may include gold (Au), silver (Ag), aluminum (Al), magnesium (Mg), lithium (Li), molybdenum (Mo), titanium (Ti), copper (Cu), or alloys thereof. The transparent conductive oxide may include indium tin oxide (“ITO”), indium zinc oxide (“IZO”), zinc oxide, indium oxide, indium gallium oxide, indium gallium zinc oxide (“IGZO”), or aluminum zinc oxide. In an embodiment, the second conductive layer ME2-I may include the same material as that of the common electrode layer COE, and the first and second conductive layers ME1-I, and ME2-I may include different materials, although this is not limiting.

Referring to FIG. 10C, a preliminary insulating layer IP-I, a pixel electrode AE, and a preliminary pixel defining layer PDL-I may be formed on the first and second conductive layers ME1-I, and ME2-I. The preliminary insulating layer IP-I may be formed on the first and second conductive layers ME1-I, and ME2-I, the pixel electrode AE may be formed on the preliminary insulating layer IP-I, and the preliminary pixel defining layer PDL-I may be formed to cover the pixel electrode AE.

Subsequently, a first photoresist PR1 may be formed on the preliminary pixel defining layer PDL-I. The first photoresist PR1 may be formed by forming a preliminary photoresist layer on the preliminary pixel defining layer PDL-I and then patterning the photoresist layer using a photomask. Through the patterning process, a first photo opening OP-PR1 that overlaps the pixel electrode AE may be defined in the first photoresist PR1.

Referring to FIG. 10D, by etching the preliminary pixel defining layer PDL-I, a light-emitting opening OP-E overlapping the pixel electrode AE may be defined. In an embodiment, a portion of the preliminary pixel defining layer PDL-I may be dry-etched using the first photoresist PR1 shown in FIG. 10C as a mask, for example. A portion of the preliminary pixel defining layer PDL-I is removed, and a light-emitting opening OP-E is defined in the preliminary pixel defining layer PDL-I. The pixel electrode AE may be exposed through the light-emitting opening OP-E.

Subsequently, the first photoresist PR1 shown in FIG. 10C is removed, and a second photoresist PR2 may be formed on the preliminary pixel defining layer PDL-I. The second photoresist PR2 may be formed by forming a preliminary photoresist layer on the preliminary pixel defining layer PDL-I and then patterning the photoresist layer using a photomask. Through the patterning process, the second photoresist PR2 may cover the pixel electrode AE.

Referring to FIG. 10E, the first and second conductive layers ME1-I, and ME2-I, the preliminary insulating layer IP-I, and the preliminary pixel defining layer PDL-I are primarily etched. The first and second conductive layers ME1-I, and ME2-I, the preliminary insulating layer IP-I, and the preliminary pixel defining layer PDL-I may be dry-etched using the second photoresist PR2 as a mask. Portions of the first and second conductive layers ME1-I, and ME2-I, the preliminary insulating layer IP-I, and the preliminary pixel defining layer PDL-I may be removed. Through this process, the second conductive pattern ME2, the insulating pattern IP, and the pixel defining layer PDL may be formed.

Referring to FIG. 10F, the first and second conductive layers ME1-I, and ME2-I are secondarily etched. As a result, the first and second conductive patterns ME1 and ME2 may be formed. The first conductive layer ME1-I may be wet-etched using the second photoresist PR2 as a mask. Accordingly, a conductive partition wall including the first and second conductive patterns ME1 and ME2 may be formed. A first recess A1 may be defined in the conductive partition wall. The light-emitting opening OP-E and the first recess A1 may be non-overlapping in a planar view. Thereafter, the second photoresist PR2 may be removed.

The wet etching process may be carried out under conditions where there is a relatively high etch selectivity between the first conductive layer ME1-I and the second conductive layer ME2-I. Accordingly, an inner sidewall of the conductive partition wall defining the first recess A1 may exhibit an undercut profile in cross-section. Specifically, the etch rate of the first conductive layer ME1-I with respect to the etching solution may be greater than that of the second conductive layer ME2-I. In such a case, the first conductive layer ME1-I may be preferentially etched. Consequently, the side surface of the first conductive pattern ME1 may be more recessed inward than that of the second conductive pattern ME2.

Referring to FIG. 10G, a light-emitting pattern EP covering the pixel electrode AE may be formed on the conductive partition wall. The light-emitting pattern EP may be formed through a deposition process of a light-emitting layer. The deposition process for the light-emitting layer may be, but not limited to, a thermal evaporation process. The light-emitting layer may be separated into the light-emitting pattern EP and a first dummy layer D1 by the first recess A1 in the conductive partition wall. That is, the light-emitting pattern EP and the first dummy layer D1 may be formed simultaneously and may include the same material as each other. The light-emitting pattern EP may surround and cover side surfaces of the insulating pattern IP and the second conductive pattern ME2. The first dummy layer D1 may be formed on the common electrode layer COE.

Referring to FIG. 10H, an opposite electrode CE electrically connected with the conductive partition wall may be formed on the light-emitting pattern EP. The opposite electrode CE may be formed through a deposition process of an opposite electrode layer. The deposition process for the opposite electrode layer may be, but not limited to, a thermal evaporation process. The opposite electrode layer may be separated into the opposite electrode CE and a second dummy layer D2 by the first recess A1 of the conductive partition wall. That is, the opposite electrode CE and the second dummy layer D2 may be formed simultaneously and may include the same material as each other. The opposite electrode CE may cover the upper surface and at least a portion of the side surfaces of the light-emitting pattern EP. The second dummy layer D2 may be formed on the first dummy layer D1.

The pixel electrode AE, the light-emitting pattern EP, and the opposite electrode CE may be sequentially stacked along the third direction DR3. The pixel electrode AE, the light-emitting pattern EP, and the opposite electrode CE together may form a light-emitting diode ED. The first dummy layer D1 and the second dummy layer D2 may be sequentially stacked along the third direction DR3.

Referring to FIG. 10I, a connection electrode SE may be formed to cover the opposite electrode CE and a bottom surface of the second conductive pattern ME2. The connection electrode SE may be formed through a deposition process of a connection electrode layer. The deposition process for the connection electrode layer may be, but not limited to, a sputtering process.

The connection electrode layer may include a conductive material. In an embodiment, the conductive material may include a metal, a transparent conductive oxide (“TCO”), or a combination thereof, for example. The metal may include gold (Au), silver (Ag), aluminum (Al), magnesium (Mg), lithium (Li), molybdenum (Mo), titanium (Ti), copper (Cu), or alloys thereof. The transparent conductive oxide may include indium tin oxide (“ITO”), indium zinc oxide (“IZO”), zinc oxide, indium oxide, indium gallium oxide, indium gallium zinc oxide (“IGZO”), or aluminum zinc oxide.

The connection electrode SE may be formed on the opposite electrode CE. The connection electrode SE may cover the opposite electrode CE and be formed to directly contact and cover the bottom surface of the second conductive pattern ME2. In an embodiment, the connection electrode SE may extend along the bottom surface of the second conductive pattern ME2 and the side surface of the first conductive pattern ME1, for example. The connection electrode SE may contact the side surface of the first conductive pattern ME1 and may also extend in a direction away from the side surface of the first conductive pattern ME1. To this end, the connection electrode SE may be formed on the first and second dummy layers D1, and D2.

Referring to FIG. 10J, a preliminary encapsulation layer LIL-I may be formed on the connection electrode SE. The preliminary encapsulation layer LIL-I may be formed through a deposition process. In an embodiment, the preliminary encapsulation layer LIL-I may be formed by a chemical vapor deposition (“CVD”) process, for example. The preliminary encapsulation layer LIL-I may be formed to cover an upper surface of the connection electrode SE. The shape of the preliminary encapsulation layer LIL-I corresponds to the shape of the connection electrode SE. The preliminary encapsulation layer LIL-I includes a first portion, which covers the top of the light-emitting diode ED, a second portion, which extends from the first portion and surrounds side surfaces of the light-emitting diode ED and the second conductive pattern ME2, and a third portion, which extends from the second portion in a direction away from the first conductive pattern ME1 and the light-emitting diode ED and disposed on the first and second dummy layers D1, and D2. A second recess A2 is defined between the second and third portions.

Referring to FIG. 10K, a portion of the preliminary encapsulation layer LIL-I that does not overlap the light-emitting diode ED may be removed. For this, a third photoresist PR3 may be formed on the preliminary encapsulation layer LIL-I. The third photoresist PR3 may be formed by forming a preliminary photoresist layer and then patterning the layer using a photomask. Through this patterning process, the third photoresist PR3 may be formed in a pattern corresponding to the light-emitting diode ED.

The preliminary encapsulation layer LIL-I and the connection electrode layer are patterned into the encapsulation pattern LIL and the connection electrode SE by the third photoresist PR3. The preliminary encapsulation layer LIL-I may be dry-etched using the third photoresist PR3 as a mask. During this process, at least a portion of the preliminary encapsulation layer LIL-I and the connection electrode layer formed on the first and second dummy layers D1, and D2 may be removed. However, due to the structure of the connection electrode SE that electrically connects the opposite electrode CE with the conductive partition wall and the shape of the encapsulation pattern LIL extending along the connection electrode SE, the second recess A2 may still be formed even when the preliminary encapsulation layer LIL-I is partially removed.

Subsequently, the first and second dummy layers D1, and D2 may be further removed. The first and second dummy layers D1, and D2 may be removed by wet etching, and the first dummy layer D1 may also be removed using a stripper. Upon removal of the first and second dummy layers D1, and D2, the first recess A1 may be formed below the encapsulation pattern LIL. The encapsulation pattern LIL may be spaced apart from the common electrode layer COE in the third direction DR3. Thereafter, the third photoresist PR3 is removed.

Referring to FIG. 10L, a reflection-reducing layer RPL may be formed on the common electrode layer COE. To prevent damage to the light-emitting diode ED during the formation of the reflection-reducing layer RPL, the reflection-reducing layer RPL may be formed after the formation of the encapsulation pattern LIL protecting the light-emitting diode ED. The reflection-reducing layer RPL may be formed to fill the space between the light-emitting diodes ED that protrude in the vertical direction. The side surfaces of the first conductive pattern ME1 and the encapsulation pattern LIL may serve as inner walls that accommodate the reflection-reducing layer RPL.

The reflection-reducing layer RPL may cover irregularities caused by the side surfaces of the first conductive pattern ME1 and the encapsulation pattern LIL. The reflection-reducing layer RPL may cover the exposed upper surface of the common electrode layer COE. The reflection-reducing layer RPL may be formed to fill the first recess A1 and the second recess A2. Accordingly, the reflection of external light caused by various electrodes and wiring in the non-light-emitting area NPXA may be reduced. The reflection-reducing layer RPL may include a material having a lower reflectance than electrodes and wiring such as the common electrode layer COE, the first and second conductive patterns ME1 and ME2, and the connection electrodes SE1, SE2, and SE3. The reflection-reducing layer RPL may include a black-colored dye or pigment. In an embodiment, the reflection-reducing layer RPL may include the same material as that of the pixel defining layer PDL, for example. In an embodiment, the reflection-reducing layer RPL may include silicon nitride (SiNx), for example.

Unlike the illustration in FIG. 10L, the reflection-reducing layer RPL may be formed on a lower encapsulation layer BIL after the lower encapsulation layer BIL has been formed on the encapsulation pattern LIL, as illustrated in FIG. 7 or 9. Moreover, as shown in FIG. 8 or 9, the reflection-reducing layer RPL may be planarized to include a flat upper surface through a polishing or ashing process. Although the upper surface of the reflection-reducing layer RPL is shown in FIG. 10L as convex with respect to the display surface, the shape of the upper surface of the reflection-reducing layer RPL is not limited thereto and may alternatively be concave.

Referring to FIG. 10M, an intermediate encapsulation layer OL and an upper encapsulation layer UIL may be formed to cover the encapsulation pattern LIL and the reflection-reducing layer RPL. The intermediate encapsulation layer OL may be formed by, but not limited to, coating an organic material on the encapsulation pattern LIL and the reflection-reducing layer RPL using an inkjet method. The intermediate encapsulation layer OL provides a planarized upper surface. The upper encapsulation layer UIL may be formed by, but not limited to, depositing an inorganic material on the intermediate encapsulation layer OL.

Although not shown in the drawing, after forming the reflection-reducing layer RPL, the lower encapsulation layer BIL may be formed to cover the reflection-reducing layer RPL and the encapsulation pattern LIL as in FIG. 6. The lower encapsulation layer BIL may be formed by, but not limited to, depositing an inorganic material on the reflection-reducing layer RPL and the encapsulation pattern LIL. In such a case, the intermediate encapsulation layer OL and the upper encapsulation layer UIL may be formed on the lower encapsulation layer BIL.

FIG. 11 is an example cross-sectional view illustrating a portion of the display panel taken along line I-I′ of FIG. 3. FIG. 11 shows an enlarged view of the first to third pixels PX_R, PX_G, and PX_B shown in FIG. 3 and is understood as a different embodiment from FIG. 4. Components that perform the same functions as those in FIG. 4 are designated with the same reference numerals, and redundant descriptions may be omitted. Additionally, the components shown in FIG. 11 will be described based on their process sequence.

Referring to FIG. 11, the display panel 100-6 includes a base substrate BL, a circuit element layer CL, a display element layer ELL, and an encapsulation layer TFE. The base substrate BL, circuit element layer CL, display element layer ELL, and encapsulation layer TFE correspond, respectively, to the base substrate BL, circuit element layer CL, display element layer ELL, and encapsulation layer TFE described with reference to FIG. 2. As described above, the base substrate BL may include or consist of various materials such as glass, metal, or plastic. The circuit element layer CL is disposed on the base substrate BL and includes a pixel circuit configured to control activation and light emission of the first to third pixels PX_R, PX_G, and PX_B.

The display element layer ELL may be disposed on the circuit element layer CL. The display element layer ELL may include an insulating layer IL, a first conductive pattern ME1, a second conductive pattern ME2, light-emitting diodes ED1, ED2, and ED3, and a pixel defining layer PDL. The light-emitting diodes ED1, ED2, and ED3 may include pixel electrodes AE1, AE2, and AE3, light-emitting patterns EP1, EP2, and EP3, and opposite electrodes CE1, CE2, and CE3.

The insulating layer IL may be disposed on the circuit element layer CL. The insulating layer IL may provide contact holes for electrically connecting the light-emitting diodes ED1, ED2, and ED3 with the pixel circuit of the circuit element layer CL. Through the contact holes, the pixel circuit of the circuit element layer CL is electrically connected with the pixel electrodes AE1, AE2, and AE3 of the light-emitting diodes ED1, ED2, and ED3. Such electrical connections may be provided at positions other than the cross-section shown in FIG. 11.

The pixel electrodes AE1, AE2, and AE3 may be disposed on the insulating layer IL. The pixel electrodes AE1, AE2, and AE3 may be arranged to overlap the first to third light-emitting areas PXA_R, PXA_G, and PXA_B. The pixel electrodes AE1, AE2, and AE3 serve as anode electrodes of the light-emitting diodes ED1, ED2, and ED3 and are electrically connected with the pixel circuit of the circuit element layer CL.

The pixel defining layer PDL may be disposed on the insulating layer IL. The pixel defining layer PDL may surround the pixel electrodes AE1, AE2, and AE3 to expose at least portions of the pixel electrodes AE1, AE2, and AE3. The pixel defining layer PDL defines the first to third light-emitting areas PXA_R, PXA_G, and PXA_B. The pixel defining layer PDL may be patterned after a preliminary pixel defining layer is formed on the pixel electrodes AE1, AE2, and AE3. This patterning may be performed in conjunction with the formation of the first conductive pattern ME1.

The first conductive pattern ME1 may be disposed on the pixel defining layer PDL. The first conductive pattern ME1 may be electrically connected with the opposite electrodes CE1, CE2, and CE3. The first conductive pattern ME1 may be disposed to overlap the non-light-emitting area NPXA. The first conductive pattern ME1 may be patterned after a first conductive layer is formed on a preliminary pixel defining layer. This patterning may be performed simultaneously with the formation of the pixel defining layer PDL.

The second conductive pattern ME2 may be disposed on the first conductive pattern ME1. The second conductive pattern ME2 may be electrically connected with the first conductive pattern ME1. The second conductive pattern ME2 may be patterned after a second conductive layer is formed on the first conductive layer. In an embodiment, the second conductive layer may be primarily etched using a photoresist as a mask, followed by secondary etching of the first conductive layer and the preliminary pixel defining layer, for example.

The side surface of the second conductive pattern ME2 may protrude further than the side surface of the first conductive pattern ME1. Due to the protruding shape of the second conductive pattern ME2, the light-emitting diodes ED1, ED2, and ED3 may be patterned on a pixel-by-pixel basis without using a mask defining pixel unit openings (e.g., an FMM). In other words, high-resolution pixel formation is achievable.

The first and second conductive patterns ME1 and ME2 are defined as a conductive partition wall that electrically connects the opposite electrodes CE1, CE2, and CE3 with the common electrode layer COE. Additionally, at least one of the first and second conductive patterns ME1 and ME2 may provide a common voltage to the opposite electrodes CE1, CE2, and CE3, similar to the common electrode layer COE described with reference to FIG. 4 and subsequent drawing figures.

The light-emitting patterns EP1, EP2, and EP3 are disposed on the pixel electrodes AE1, AE2, and AE3. The light-emitting patterns EP1, EP2, and EP3 may be formed through a deposition process of a light-emitting layer. The light-emitting layer may be separated into the light-emitting patterns EP1, EP2, and EP3 and a first dummy layer D1 by the structure of the second conductive pattern ME2, which protrudes further than the first conductive pattern ME1. The first dummy layer D1 may be formed on the second conductive pattern ME2 and, although not shown, may be removed in a subsequent process.

The opposite electrodes CE1, CE2, and CE3 are disposed on the light-emitting patterns EP1, EP2, and EP3. The opposite electrodes CE1, CE2, and CE3 serve as cathode electrodes of the light-emitting diodes ED1, ED2, and ED3 and are electrically connected with the first conductive pattern ME1. The opposite electrodes CE may be formed through a deposition process of an opposite electrode layer. The opposite electrode layer may be separated into the opposite electrodes CE1, CE2, and CE3 and a second dummy layer D2 by the structure of the second conductive pattern ME2, which protrudes further than the first conductive pattern ME1. The second dummy layer D2 may be formed on the first dummy layer D1 and, although not shown, may be removed in a subsequent process.

The encapsulation layer TFE is disposed on the display element layer ELL. The encapsulation layer TFE includes encapsulation patterns LIL1, LIL2, and LIL3, a reflection-reducing layer RPL, an intermediate encapsulation layer OL, and an upper encapsulation layer UIL. It shall be appreciated that the components disposed in the encapsulation layer TFE are illustrative, and additional encapsulation layers or encapsulation patterns may also be provided.

The encapsulation patterns LIL1, LIL2, and LIL3 may cover the upper surfaces of the light-emitting diodes ED1, ED2, and ED3. The encapsulation patterns LIL1, LIL2, and LIL3 may be arranged to overlap the first to third light-emitting areas PXA_R, PXA_G, and PXA_B. Since the encapsulation patterns LIL1, LIL2, and LIL3 extend along an anchor-shaped profile defined by the structure of the second conductive pattern ME2 protruding further than the first conductive pattern ME1, the encapsulation patterns LIL1, LIL2, and LIL3 may extend not only over the top surfaces of the light-emitting diodes ED1, ED2, and ED3 but also over the side surfaces of the first and second conductive patterns ME1 and ME2 and the upper surfaces of the first and second dummy layers D1, and D2, thereby robustly covering the internal components. The encapsulation patterns LIL1, LIL2, and LIL3 includes a first portion disposed on the light-emitting diodes ED1, ED2, and ED3, a second portion extending from the first portion and disposed around a side surface of the second conductive pattern ME2, and a third portion extending from the second portion away from the light-emitting diodes ED1, ED2, and ED3. The first and second dummy layers D1, and D2 may be removed in a subsequent process, and in which case, a recess may be defined between the encapsulation patterns LIL1, LIL2, and LIL3 and the common electrode layer (i.e., the first and second conductive patterns ME1 and ME2).

The reflection-reducing layer RPL may be disposed on the common electrode layer (i.e., the first and second conductive patterns ME1 and ME2) to reduce the reflection of external light caused by various electrodes and wiring. The reflection-reducing layer RPL may be disposed to overlap the non-light-emitting area NPXA. The reflection-reducing layer RPL may surround portions of the encapsulation patterns LIL1, LIL2, and LIL3. The reflection-reducing layer RPL may surround at least part of the side surfaces of the first conductive pattern ME1 and the encapsulation patterns LIL1, LIL2, and LIL3. When a recess defined between the encapsulation patterns LIL1, LIL2, and LIL3 and the common electrode layer (i.e., the first and second conductive patterns ME1 and ME2), the reflection-reducing layer RPL may fill the recess. The side surfaces of the encapsulation patterns LIL1, LIL2, and LIL3 may serve as inner walls for accommodating the reflection-reducing layer RPL.

The shape of the reflection-reducing layer RPL is not limited to that shown in FIG. 11. Although the upper surface of the reflection-reducing layer RPL is illustrated as convex with respect to the display surface, the reflection-reducing layer RPL may alternatively include a flat or concave upper surface. Furthermore, a lower encapsulation layer may be disposed between the reflection-reducing layer RPL and the encapsulation patterns LIL1, LIL2, and LIL3.

The intermediate encapsulation layer OL may be disposed on the encapsulation patterns LIL1, LIL2, and LIL3 and the reflection-reducing layer RPL to cover the encapsulation patterns LIL1, LIL2, and LIL3 and the reflection-reducing layer RPL. The upper encapsulation layer UIL may be disposed on the intermediate encapsulation layer OL.

The display device DD according to the above-described embodiment may be applied to various electronic devices. An electronic device in an embodiment includes the above-described display device and may further include additional modules or devices having functions other than as a display device.

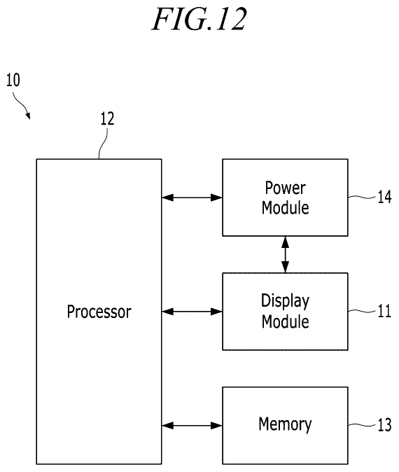

FIG. 12 is a block diagram of an electronic device. Referring to FIG. 12, an electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may have stored therein data information desired for the operation of the processor 12 or the display module 11. Once the processor 12 executes an application stored in the memory 13, image data signals and/or input control signals may be transferred to the display module 11, which may process the received signals and output visual information via a display screen.

The power module 14 may include a power supply module, such as a power adapter or battery device, and a power conversion module configured to convert the supplied power to generate power desired for the operation of the electronic device 10.

At least one of the components of the electronic device 10 described above may be included in the display device DD according to the above-described embodiments. Additionally, some of the individual modules functionally included within a single module may be included in the display device, while others may be provided separately from the display device. In an embodiment, the display device may include the display module 11, while the processor 12, memory 13, and power module 14 may be provided as parts of another device within the electronic device 10 rather than within the display device itself, for example.

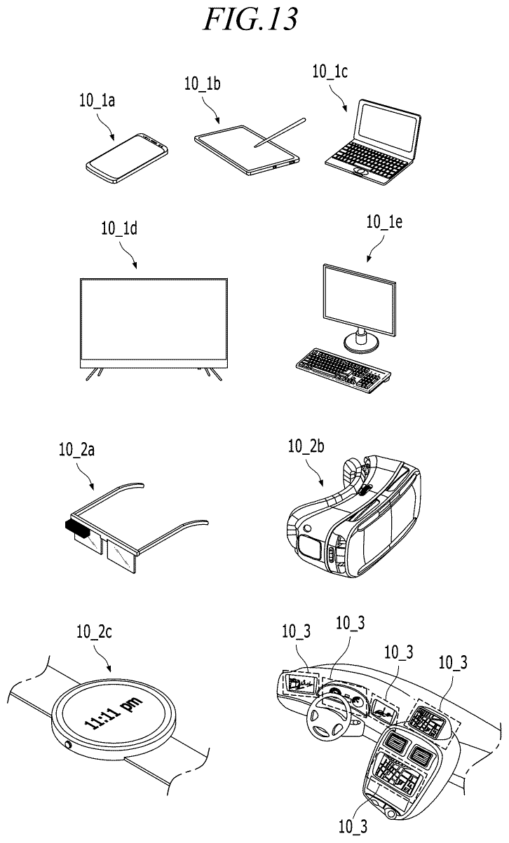

FIG. 13 illustrates schematic views of embodiments of electronic devices. Referring to FIG. 13, various electronic devices to which the display device in embodiments is applied may include not only image displaying electronic devices, such as a smartphone 10_1a, a tablet PC 10_1b, a laptop computer 10_1c, a television (“TV”) 10_1d, or a desktop monitor 10_1e, but also wearable electronic devices including display modules, such as smart glasses 10_2a, head-mounted displays 10_2b, and smartwatches 10_2c, and automotive electronic devices 10_3 including display modules, such as a center information display (“CID”) disposed on an instrument panel, center fascia, or dashboard of a vehicle, or a room mirror display.

Hitherto, predetermined preferred embodiments of the disclosure have been described above, but these are merely exemplary and are not intended to limit the disclosure. Those skilled in the art to which the disclosure pertains may make various modifications and changes to the embodiments by adding, changing, deleting, or adding predetermined elements, without departing from the scope of the technical ideas of the disclosure as set forth in the claims, and such modifications and changes should also be regarded as being within the scope of the disclosure.

What is claimed is:

1. A display device comprising:
a base substrate;
a circuit element layer disposed on the base substrate and comprising a pixel circuit;
a light-emitting element disposed on the circuit element layer, the light-emitting element comprising:
a pixel electrode electrically connected to the pixel circuit;
a light-emitting pattern disposed on the pixel electrode; and
an opposite electrode facing the pixel electrode across the light-emitting pattern;
a conductive partition wall disposed between the circuit element layer and the light-emitting element and electrically connected with the opposite electrode;
a common electrode layer disposed between the circuit element layer and the conductive partition wall and electrically connected with the conductive partition wall;
an encapsulation pattern covering the light-emitting element and surrounding at least a portion of the conductive partition wall; and
a reflection-reducing layer disposed on the common electrode layer, surrounding at least a portion of the encapsulation pattern, and having a lower reflectance than a reflectance of the common electrode layer.

2. The display device of claim 1, wherein the conductive partition wall comprises:
a first conductive pattern in contact with the common electrode layer; and
a second conductive pattern disposed on the first conductive pattern and protruding from a side surface of the first conductive pattern on the first conductive pattern,
wherein a portion of the encapsulation pattern is disposed between the second conductive pattern and the common electrode layer.

3. The display device of claim 1, wherein the light-emitting pattern surrounds a portion of a side surface of the conductive partition wall,
wherein a portion of the encapsulation pattern is disposed between the light-emitting pattern and the common electrode layer, and
wherein the light-emitting pattern faces the reflection-reducing layer across the encapsulation pattern.

4. The display device of claim 1, wherein the opposite electrode surrounds the light-emitting pattern,
wherein a portion of the encapsulation pattern is disposed between the opposite electrode and the common electrode layer, and
wherein the opposite electrode faces the reflection-reducing layer across the encapsulation pattern.

5. The display device of claim 1, further comprising a connection electrode disposed between the opposite electrode and the encapsulation pattern, being in contact with the opposite electrode and the conductive partition wall, and surrounding a portion of a side surface of the conductive partition wall,
wherein the opposite electrode is electrically connected to the common electrode layer through the conductive partition wall and the connection electrode, and
wherein the connection electrode faces the reflection-reducing layer across the encapsulation pattern.

6. The display device of claim 1, further comprising a pixel defining layer surrounding the pixel electrode and exposing a portion of the pixel electrode,
wherein the light-emitting pattern covers the pixel defining layer and is disposed between the pixel defining layer and the reflection-reducing layer.

7. The display device of claim 1, wherein a portion of the reflection-reducing layer is disposed between the encapsulation pattern and the common electrode layer.

8. The display device of claim 7, wherein the reflection-reducing layer contacts the conductive partition wall between the encapsulation pattern and the common electrode layer.

9. The display device of claim 1, wherein the encapsulation pattern comprises a first portion disposed on the light-emitting element and covering the light-emitting element, a second portion extending from the first portion and surrounding a side surface of the light-emitting element, and a third portion extending from the second portion away from the light-emitting element, and
wherein a portion of the reflection-reducing layer is disposed in a recess defined by the second portion and the third portion.

10. The display device of claim 1, further comprising:
a lower encapsulation layer disposed on the reflection-reducing layer and the encapsulation pattern;
an intermediate encapsulation layer including a planar upper surface and disposed on the lower encapsulation layer; and
an upper encapsulation layer disposed on the intermediate encapsulation layer.

11. The display device of claim 1, further comprising:
a lower encapsulation layer covering the encapsulation pattern; and
an intermediate encapsulation layer covering the lower encapsulation layer and the reflection-reducing layer,
wherein the reflection-reducing layer is disposed between the lower encapsulation layer and the intermediate encapsulation layer.

12. The display device of claim 11, wherein the encapsulation pattern comprises a first portion disposed on the light-emitting element and covering the light-emitting element, a second portion extending from the first portion and surrounding a side surface of the light-emitting element, and a third portion extending from the second portion away from the light-emitting element,
wherein the lower encapsulation layer extends along the first portion, the second portion, and the third portion on the encapsulation pattern, and
wherein a portion of the reflection-reducing layer is disposed in a recess defined by the lower encapsulation layer extending along the second portion and the third portion.

13. The display device of claim 1, wherein the reflection-reducing layer includes a planar upper surface.

14. The display device of claim 13, wherein the encapsulation pattern includes a planar upper surface continuing from the upper surface of the reflection-reducing layer.

15. The display device of claim 1, wherein the light-emitting element and the encapsulation pattern are provided in plural and arranged in a two-dimensional array in a plan view, and
wherein a plurality of encapsulation patterns is separated from each other by the reflection-reducing layer.

16. A display device comprising:
a base substrate;
a circuit element layer disposed on the base substrate and comprising a pixel circuit;
a light-emitting element disposed on the circuit element layer, the light-emitting element comprising:
a pixel electrode electrically connected to the pixel circuit;
a light-emitting pattern disposed on the pixel electrode; and
an opposite electrode facing the pixel electrode across the light-emitting pattern;
a conductive partition wall comprising:
a first conductive pattern including a side surface electrically connected with the opposite electrode; and
a second conductive pattern disposed on the first conductive pattern and protruding from the side surface;
an encapsulation pattern comprising:
a first portion disposed on the light-emitting element and covering the light-emitting element;
a second portion extending from the first portion and disposed around a side surface of the second conductive pattern; and
a third portion extending from the second portion away from the light-emitting element; and
a reflection-reducing layer surrounding the third portion and having a lower reflectance than a reflectance of the conductive partition wall.

17. The display device of claim 16, wherein the light-emitting element is disposed on the second conductive pattern, and the reflection-reducing layer is non-overlapping with the first conductive pattern.

18. The display device of claim 16, wherein the light-emitting element is spaced apart from the second conductive pattern, and the reflection-reducing layer is disposed on the first conductive pattern and the second conductive pattern.

19. An electronic device comprising a display device, the display device comprising:
a base substrate;
a circuit element layer disposed on the base substrate and comprising a pixel circuit;
a light-emitting element disposed on the circuit element layer, the light-emitting element comprising:
a pixel electrode electrically connected to the pixel circuit;
a light-emitting pattern disposed on the pixel electrode; and
an opposite electrode facing the pixel electrode across the light-emitting pattern;
a conductive partition wall disposed between the circuit element layer and the light-emitting element and electrically connected with the opposite electrode;
a common electrode layer disposed between the circuit element layer and the conductive partition wall and electrically connected with the conductive partition wall;
an encapsulation pattern covering the light-emitting element and surrounding at least a portion of the conductive partition wall; and
a reflection-reducing layer disposed on the common electrode layer, surrounding at least a portion of the encapsulation pattern, and having a lower reflectance than a reflectance of the common electrode layer.

20. The electronic device of claim 19, further comprising:
a processor configured to execute an application and to transfer image data signals to the display device;
a memory in which data information for executing the application is stored; and
a power module configured to supply power to the display device, the processor, and the memory,
wherein the display device output image information based on the image data signals.
